(19) United States
(12) Patent Application Publication
(10) Pub. No.: US 2011/0260761 A1
(43) Pub. Date: Oct. 27, 2011

(54) TEMPERATURE COMPENSATION IN A PHASE-LOCKED LOOP

(75) Inventors: Niall Kearney, Killeagh (IE); Aidan Murphy, Innishannon (IE)

(73) Assignee: FREESCALE SEMICONDUCTOR, INC.

(21) Appl. No.: 13/121,693

(22) PCT Filed: Oct. 17, 2008
(86) PCT No.: PCT/IB2008/054274

§ 371 Date: Mar. 30, 2011

(30) Foreign Application Priority Data
Apr. 13, 2009 (CN) 200910029409.5

(51) Int. Cl. H03L 7/08

(52) U.S. Cl. 327/156

(57) ABSTRACT

An integrated circuit comprises a digital phase-locked loop for a wireless communications unit. The digital phase-locked loop comprises a voltage controlled oscillator and a digital tuning subsystem. An input of the digital tuning subsystem receives the output signal from the voltage controlled oscillator, and an output of the digital tuning subsystem is supplied to the voltage controlled oscillator. A digital voltage generator is adapted to store at least two predetermined forcing voltages. The digital voltage generator is adapted to select one of the at least two predetermined forcing voltages, in dependence on a current temperature value, and to supply it as a forcing voltage to an input of the voltage controlled oscillator, prior to the phase locked loop achieving lock. A wireless communication unit and a method of tuning a phase-locked loop are also provided.

### FIELD OF THE INVENTION

The technical field relates to phase-locked loop circuits for wireless communication units. The invention is applicable to, but not limited to, a clock synthesizer circuit in a wireless communication unit.

### BACKGROUND OF THE INVENTION

Phase locked loops are used extensively in digital frequency or clock generation circuitry. A major application is in wireless communication units.

Wireless communication units usually work as part of a larger communication system, such as the Global System for Mobile communications (GSM) cellular telephone system. Such systems may use a broadcast signal to provide a reference frequency. An example of such a broadcast signal is the Frequency Correction Channel (FCCH) in a GSM system. The broadcast signal is generally transmitted from one or more base transceiver stations.

A wireless communication unit can use the broadcast signal to calibrate its operating frequency. The ‘operating frequency’ is the frequency on which the wireless communication unit transmits and receives. In effect, the wireless communication unit is using the broadcast signal to synchronise its internal frequency generation circuits to a centralized timing system. A digital phase locked loop may be used to achieve this.

When a phase locked loop is used in a mobile wireless communication unit, for example to synthesize a clock signal, there are certain basic performance parameters that must be met. One such parameter is the temperature range over which the phase locked loop must be able to maintain the ‘lock’ condition. A phase-locked loop is in a ‘locked’ condition when it is able to generate a signal with a frequency that remains constant within a very narrow range.

An overview of phase locked loops in digital integrated circuits is provided in ‘Phase-Locked Loop Design Fundamentals’, G. Nash, Motorola Applications Note AN535, 7/93, see: http://www.circuitsage.com/pll/pll fundamentals.pdf

The voltage controlled oscillator (VCO) of a phase locked loop provides a frequency that varies in dependence on the voltage supplied to it. The voltage supplied to the voltage controlled oscillator is the ‘tuning voltage’. However, the output of the VCO also varies with temperature, i.e. it has a non-zero temperature co-efficient.

VCO temperature coefficient is a particular problem for a phase locked loop where:
(i) lock is to be maintained over an extended period of time; and
(ii) there are extreme changes in ambient temperature.

Here, the VCO tuning voltage may be shifted due to a temperature dependent ‘frequency pulling effect’ within the phase locked loop. The resulting changes in the tuning voltage may be so great as to exceed the allowable range of tuning voltage operation. The limits on the tuning voltage for acceptable operation are, in fact, set by the capabilities of components within the phase locked loop. In particular, many phase locked loops employ a charge pump, and the charge pump has a particular compliance range. The ‘XOR’ (exclusive or) circuit of a phase locked loop may also only operate linearly over a finite range of inputs.

If the tuning voltage is pushed beyond the acceptable limits, there is likely to be a complete loss of lock by the phase locked loop. If this occurs, then a call or a data transfer being made by the wireless communication unit is likely to be lost.

Prior art arrangements have sought to provide a signal to the phase locked loop to compensate for temperature variations. There are many examples in the prior art of a temperature dependent bias signal being used to provide open loop VCO temperature compensation.

Prior art approaches tend to show a number of disadvantages. One problem is noise, which results from adding a bias voltage into the loop filter in normal operation. In addition, prior art arrangements may show phase discontinuities, because adjustments are made during operation.

A further problem with prior art arrangements is the complexity of the hardware that is required. In particular, a low noise analogue to digital converter (ADC) may be required.

Open loop VCO bias techniques can be particularly difficult for wideband tuning VCOs. For example, one known wireless mobile communications unit is required to operate at frequencies between 2.496 GHz and 2.912 GHz. To tune over such a wide frequency range, a large change is required in the balance of varactors, in accumulation and depletion regions.

One example of a prior art arrangement is shown in ‘A digitally temperature compensated compact PLL module’, T Kobayashi et al, IEEE International Frequency Control Symposium 1997.

Appended FIG. 1 shows a simplified circuit 100 proposed by Kobayashi et al. that provides a temperature-compensated phase locked loop, which includes a temperature sensor.

In circuit 100, an input signal is fed to one input of a phase comparator 110. The output of phase comparator 110 is fed to one input of adder 120. The output of adder 120 is connected to VCO 130. After VCO 130, a first divider 140 divides the frequency of the output signal by a first factor ‘N’, in order to provide the output signal from the circuit 100. The output signal is also provided to a second divider 150, which divides its frequency by a second factor ‘M’. The output of second divider 150 is fed to the second input of phase comparator 110.

An electrically erasable programmable read-only memory (EEPROM) 160 contains pre-characterised compensation voltages. These compensation voltages can correct for temperature variations in the crystal unit of VCO 130. The compensation voltage at any particular time is selected on the basis of the temperature measured by a temperature sensor at that time. The compensation voltage is added to the second input of adder 120, during operation of the phase locked loop, to provide a correction. However, the addition of this compensation voltage introduces both noise and transient phase discontinuities. These are some of the disadvantageous side effects of the temperature compensation scheme proposed by Kobayashi et al.

### SUMMARY OF THE INVENTION

The examples described herein provide an integrated circuit with a phase-locked loop for a wireless communications unit, as described in the accompanying claims. The present invention also provides a method of tuning a phase-locked loop for a wireless communications unit, as described in the accompanying claims. A computer program product for implementing the method is also provided.

Specific exemplary embodiments of the invention are set forth in the dependent claims.

These and other aspects of the invention will be apparent from, and elucidated with reference to, the exemplary embodiments described hereinafter.

### BRIEF DESCRIPTION OF THE DRAWINGS

Further details, aspects and exemplary embodiments of the invention will be described, by way of example only, with reference to the drawings. Elements in the figures are illustrated for simplicity and clarity, and have not necessarily been drawn to scale.

FIG. 1 schematically shows a prior art phase locked loop.

FIG. 2 illustrates an example of a circuit.

FIG. 3 illustrates a typical VCO tuning sensitivity characteristic.

FIG. 4 illustrates the available frequency tracking range of a phase-locked loop, as a function of initial tuning line voltage value in the presence of pulling effects.

FIG. 5 illustrates the typical temperature tracking range achievable by the example circuit of FIG. 2.

FIG. 6 shows an example of a method of tuning a phase-locked loop in the form of a flowchart.

### DETAILED DESCRIPTION OF EMBODIMENTS OF THE INVENTION

Digital phase locked loops are normally subject to several design constraints. These constraints may be particularly important when the phase-locked loop is part of an integrated circuit, and/or has to be included in a portable device such as a wireless communications unit.

One design aim is often to obtain the widest possible range of temperatures over which the phase-locked loop can maintain lock. For example, some phase-locked loops in mobile communication units must be able to operate down to −30C (minus 30 degrees Centigrade) and up to +85C.

Other key design constraints are:
(i) The maximum available voltage for operating the circuit elements of the phase locked loop.
(ii) The limit on physical area available for any components that cannot be integrated into an integrated circuit, e.g. large capacitors.
(iii) The need to minimize complexity, in order to simplify manufacture and testing, and to enhance reliability in operation.

The examples of the invention described herein provide a phase-locked loop that may be used in an integrated circuit. The phase-locked loop may, for example, be used to provide a clock synthesizer circuit in a mobile wireless communications unit. The phase-locked loop may be arranged to function with only a 1.2V power supply, rather than the higher voltages typically used with prior art phase-locked loops.

The example phase-locked loop may be arranged to:
(i) Maintain lock for very long periods of time, for example several tens of minutes, and may maintain lock indefinitely; and
(ii) Function over a temperature range as wide as, for example, −30C to +85C.

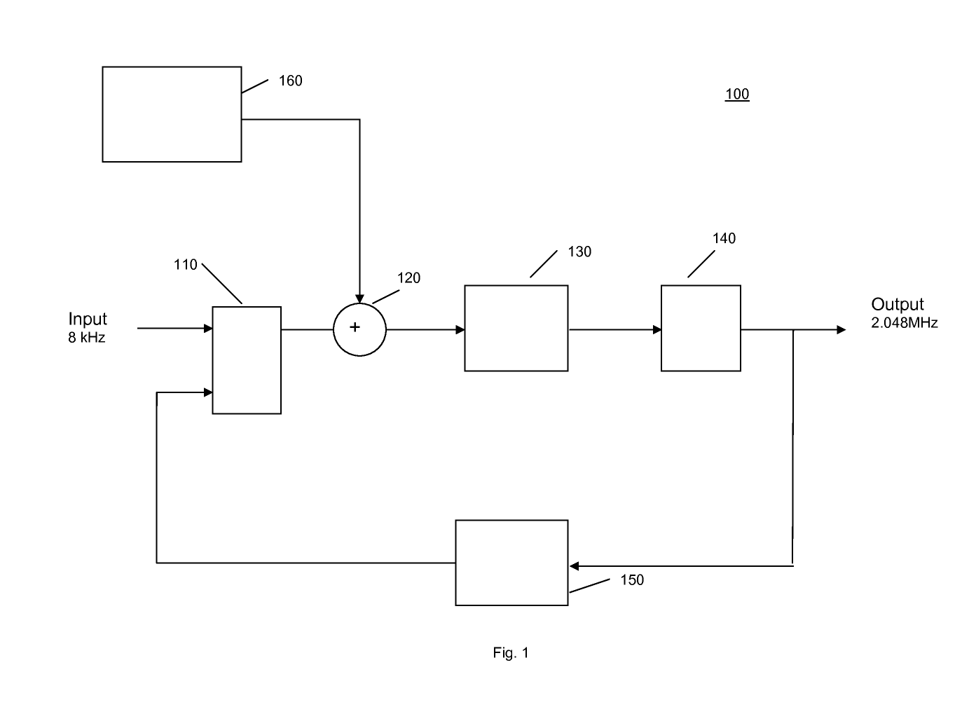

Prior art phase-locked loops in radio frequency applications are normally also designed to maximize the period for which lock can be held, and to maximize the temperature over which lock can be held. To do this, however, they typically employ a temperature compensation loop that is active after the phase-locked loop has achieved lock. This is the case with the T. Kobayashi et al prior art arrangement shown in FIG. 1. Such a temperature compensation loop requires additional circuit area and power, and may cause phase jumps and noise during operation of the phase-locked loop.

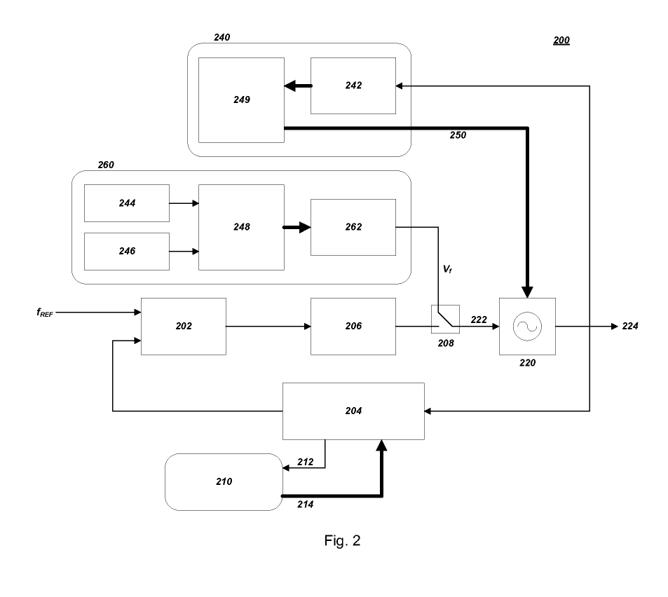

FIG. 2 shows an example of a phase locked loop 200 of the present invention.

In summary, phase locked loop 200 of FIG. 2 may comprise: a voltage controlled oscillator 220; a digital tuning sub-system 240; and a digital voltage generator 260. Voltage controlled oscillator 220 has an input 222, and provides an output signal 224 at output 226. The input of digital tuning subsystem 240 may be connected to output 226 of the voltage controlled oscillator 220. This connection allows digital tuning subsystem 240 to receive the output signal 224 from the voltage controlled oscillator 220. Digital tuning subsystem 240 provides an output to voltage controlled oscillator 220. Digital voltage generator 260 is provided for generating a forcing voltage Vf. Digital voltage generator 260 is adapted:
(i) to store at least two predetermined forcing voltages Vf1 . . . Vfn;
(ii) to select as a forcing voltage Vf one of the at least two predetermined forcing voltages Vf1 . . . Vfn, in dependence on a current temperature value T; and
(iii) to supply forcing voltage Vf as a tuning line voltage to an input 222 of voltage controlled oscillator 220 only until phase locked loop 200 achieves lock.

The example illustrated in FIG. 2 will now be considered in more detail, in order to show one way in which the exemplary circuit may function. However, a variety of alternatives to these detailed features are possible.

Phase detector 202 has a reference signal Fref as one input. Fref may be a signal with a constant, known frequency. A signal from feedback divider 204 provides the other input to phase detector 202. Phase detector 202 generates an error signal, which is applied to loop filter 206. Phase locked loops are however possible with alternative circuit elements to phase detector 202 and loop filter 206.

A switch 208 allows either the output signal of loop filter 206 or forcing voltage Vf to be selectively connected to input 222 of voltage controlled oscillator 220. Forcing voltage Vf acts as a reference bias for the tuning line voltage of voltage controlled oscillator 220.

The output signal 224 of voltage controlled oscillator 220 is input to feedback divider 204. Feedback divider 204 may be operated in a ‘fractional-N’ mode, by employing an appropriate logical control. In ‘fractional-N’ mode, feedback divider 204 divides the output signal 224 from voltage controlled oscillator 220 by an integer number N. The logical control may, for example, be provided via delta-sigma modulator logic 210, which is clocked by an output 212 from feedback divider 204. Delta-sigma modulator 210 controls the divider modulus, via control word 214.

Digital tuning subsystem 240 includes a frequency counter 242, which measures the frequency of output signal 224 during the initial tuning process. Digital tuning subsystem 240 also comprises logic controller 249. Logic controller 249 generates a digital tuning word 250, which is output to VCO 220.

The arrangement of the digital voltage generator 260 will now be considered in more detail.
(i) A temperature sensor 244 may be used to measure the temperature of the integrated circuit die at the time when lock of the phase-locked loop is initiated.
(ii) Look up table 246 may be used to store predetermined values of forcing voltage Vf. Each predetermined value Vf1 . . . Vfn of forcing voltage Vf is a value of the optimum loop bias voltage for a particular range of temperatures T that is measured by temperature sensor 244. Look-up table 246 may also be adapted to store at least two values KT1 . . . KTm of a voltage controlled oscillator temperature co-efficient KT, and a frequency value F1 . . . Fm for each of the at least two values KT1 . . . KTm. Values F1 . . . Fm correspond to different output frequencies of voltage controlled oscillator 220.
(iii) Logic controller 248 may be adapted to select a forcing voltage Vf from the at least two predetermined forcing voltages Vf1 . . . Vfn, based on the measurement result from temperature sensor 244.
(iv) Digital-to-analogue converter 262 may be used to generate the appropriate forcing voltage Vf during the digital tuning process, based on the value of Vf supplied from logic controller 248. Digital-to-analogue converter 262 supplies forcing voltage Vf to voltage controlled oscillator 220.

In the example circuit of FIG. 2, therefore, digital voltage generator 260 is adapted to select the forcing voltage Vf on the basis of the current temperature value T, and the temperature co-efficient KT corresponding to the frequency of the output signal from the voltage controlled oscillator. The forcing voltage Vf is applied to the VCO 220 via switch 208, during the digital tuning process. However, the example circuit may alternatively be arranged to select the forcing voltage Vf only on the basis of the current temperature value T. The selected forcing voltage Vf for the current temperature value T therefore improves the tracking range of the phase-locked loop 200 when the phase-locked loop is released to lock

In order to understand how the example circuit of FIG. 2 differs from the prior art, it is important to consider the tuning phase in prior art systems. Typically, in prior art systems, a digital tuning algorithm operates prior to the phase-locked loop achieving lock. During operation of the digital tuning algorithm, a fixed mid-scale voltage is applied as the tuning line voltage of the voltage controlled oscillator, and the phase locked loop is operated in an open loop configuration. Here ‘mid-scale’ means a voltage of roughly half the maximum available supply voltage VDD. If the maximum available supply voltage on the integrated circuit were 1.2V, then a fixed voltage of 0.6V would be applied as the tuning line voltage with the prior art, during operation of the digital tuning algorithm.

In such prior art arrangements, the free running frequency of the voltage controlled oscillator is measured, for example by using a digital counter. The digital counter is gated ‘on’ for a precisely known period of time. At the end of that period of time, the contents of the counter provide a direct measure of the voltage controlled oscillator frequency. By this means, a binary search algorithm may be employed to adjust the amount of capacitance present in the voltage controlled oscillator tank circuit. The adjustment of capacitance changes the frequency of the voltage controlled oscillator, which can therefore be brought closer to a desired frequency. The adjustment may be made by applying appropriate bias voltages to an array of varactors within the tank circuit.

The adjustment in the prior art system continues until the error between the free running frequency of the voltage controlled oscillator and the desired target frequency after lock has been minimized. In all, the execution of the tuning algorithm typically may have a duration of a few tens of microseconds.

The tuning algorithm of the prior art effectively serves to constrain the tuning line voltage, and when this has been achieved the phase-locked loop commences normal closed loop operation. The degree of constraint achievable is determined by, in combination, the sensitivity of the voltage controlled oscillator analogue tuning port, and the frequency resolution of the digital tuning. At lock, the tuning line voltage will be very close to the mid range value of VDD/2 applied during the digital tuning algorithm execution.

In accordance with the example circuit of FIG. 2, in contrast, the tuning line voltage supplied to the voltage controlled oscillator is forced to take on a particular value, Vf, during operation of the digital tuning algorithm. The particular value of Vf is selected so as to improve, and where possible optimize, the available temperature tracking range of the phase-locked loop after it has achieved lock. The particular forcing voltage Vf is selected from at least two predetermined forcing voltages, and the selection is made on the basis of the temperature T when the digital tuning algorithm commences. Considering again the example of an integrated circuit with a maximum available supply voltage of 1.2V, clearly at least one of the predetermined forcing voltages will differ from the 0.6V that was used as the tuning line voltage with the prior art arrangement discussed above.

In this manner, the example circuit of FIG. 2 may serve to extend the ability of a phase-locked loop to compensate temperature-induced frequency shifts. In order to understand this ability, it is first necessary to understand the limitations of prior art arrangements for tuning voltage controlled oscillators.

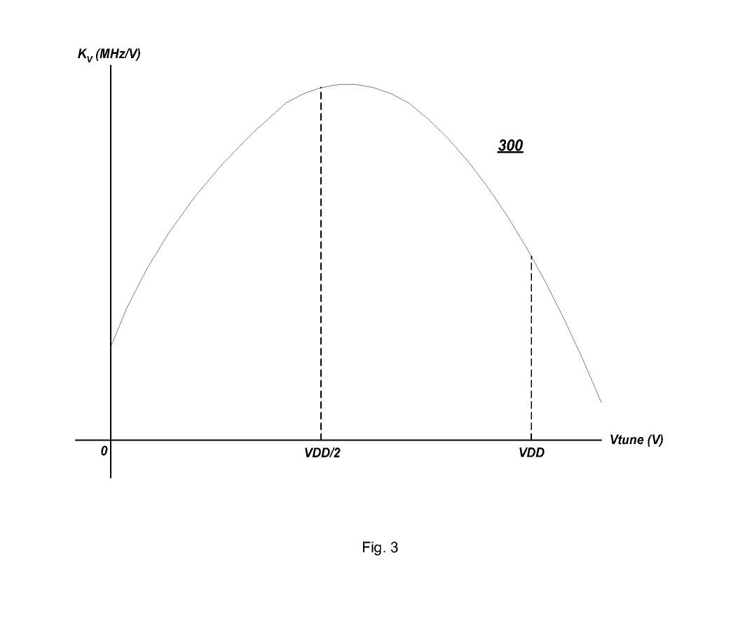

FIG. 3 shows a typical tuning sensitivity characteristic for any known voltage controlled oscillator. In FIG. 3, the x-axis shows the tuning voltage. The y-axis shows the amount that the output frequency of the voltage controlled oscillator changes, for each unit change in the tuning voltage. This parameter of a voltage controlled oscillator is usually referred to as Kᵥ.

The ‘inverted U’ shape of the curve of FIG. 3 shows that the tuning sensitivity Kv:
(i) increases with an increasing tuning voltage at lower values of the tuning voltage; and
(ii) decreases with an increasing tuning voltage, at higher values of the tuning voltage.

In normal use of a phase locked loop, the tuning line voltage is not allowed to vary all the way down to 0V, or up to VDD, i.e. these extreme voltages cannot be used. This constraint is due to concerns such as linearity of the phase detector, and device ‘headroom’, which is the amount by which the output frequency can vary up or down. As a consequence, the available range over which the tuning line voltage can vary is usually limited to particular lower and upper limit values. These limit values are referred to henceforth as VLow_Limit and VHigh_Limit respectively.

If the supply voltage VDD on the integrated circuit is limited to 1.2V, then VDD/2=0.6V. In this case:
(i) A typical value of the lower limit might be VLow_Limit=0.35V; and
(ii) A typical value of the upper limit might be VHigh_Limit=0.85V.

Assume, for a typical phase locked loop, that the initial tuning line voltage when the loop is locked is Vlnit. In normal operation of the phase locked loop, the amounts of available frequency tracking range in the positive and negative directions are given by:

Δƒₚₒₛ(V_{Init})=∫_{V}_{_{Init}}^{V}^{_{High}}_{—Limit}K_{V}(V)dV

Δƒ_{neg}(V_{Init})=∫_{V}_{_{Init}}^{V}^{_{Low}}_{—Limit}K_{V}(V)dV

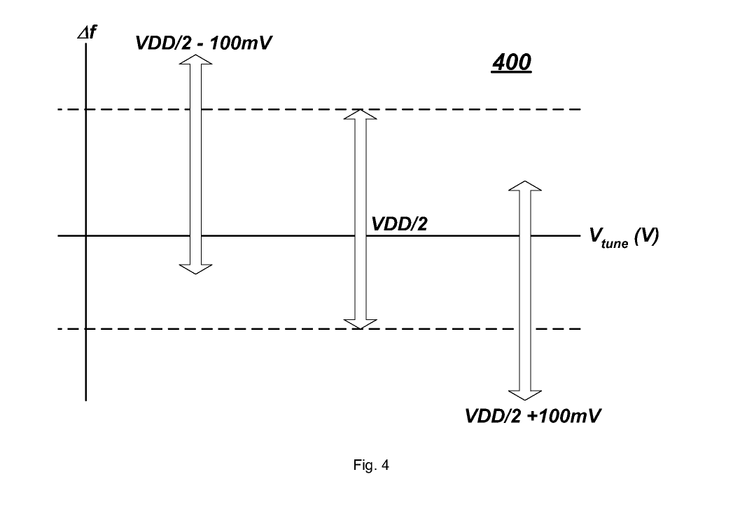

Representative tracking ranges are graphically illustrated in FIG. 4 for three values of Vlnit. The y-axis shows the tracking range. The value of Vlnit is written to the right of the three ranges that are indicated by vertical arrows. The three values of Vlnit are: (VDD/2)−100 mV, VDD/2 and (VDD/2)+100 mV.

From FIG. 4, it can be seen that the centre of the available tracking range is different for each value of Vlnit. This behavior of a phase locked loop is advantageously exploited in the example circuit of FIG. 2.

In the prior art, following the execution of the digital tuning algorithm, the lock voltage is always designed to be very close to the mid-scale value VDD/2, whatever the temperature of the phase locked loop during operation of the tuning algorithm. As a consequence, the available tuning line voltage range for temperature variation tracking will only be maximized if, by chance, the loop lock happens to be initiated at a mid range ambient temperature. If, instead, lock is initiated at one extreme of the required operating temperature range, then the ability of the loop to inherently track temperature frequency pulling effects is likely to be compromised. This is a significant drawback of the prior art.

The invention specifically addresses this in one example by sensing the ambient temperature when lock is initiated. The invention involves adjusting the tuning line voltage that is applied to the voltage controlled oscillator during digital tuning, in dependence on the ambient temperature measured. For all ambient temperatures, other than those in the mid-range, the adjustment is such that the resulting tuning line voltage value, when the loop is released to lock, is significantly different to the mid-range value VDD/2. The tuning line voltage value is therefore always arranged such as to increase the available voltage range for temperature tracking by the phase locked loop, in the direction of expected maximum temperature variation.

By way of example, consider a phase locked loop that achieves lock at the high extreme of the temperature range of operation, say 85C. Assume further that the VCO temperature coefficient is such that decreasing temperature causes the tuning line voltage to drop in closed loop operation. In this case, it is advantageous for the initial tuning line voltage at lock to be higher than the nominal mid-range value VDD/2. If the temperature drops after the phase-locked loop has achieved lock, then the phase locked loop has a greater tuning line voltage range available for tracking the temperature pulling effect, than would have been the case with a tuning line voltage of VDD/2.

This improvement is achieved by taking advantage of the information from the temperature sensor 244 at the time when lock is initiated. In the example in the previous paragraph, the measurement from the temperature sensor 244 lead to selection of a forcing voltage Vf that is higher than a mid-scale value VDD/2. A measurement from temperature sensor 244 that indicated a temperature T below the mid-range would, instead, have lead to a forcing voltage that was lower than the mid-scale value VDD/2.

The values of the predetermined forcing voltages Vf1 . . . Vfn to be used at each associated temperature T1 . . . Tn may be derived directly from knowledge of typical temperature coefficient information for the voltage controlled oscillator. The temperature measurement can then lead directly to a selection of an appropriate tuning line voltage Vf as a tuning line bias setting from look up table 246, which stores the bias settings Vf1...Vfn and their corresponding temperatures. However, as explained in connection with the example circuit of FIG. 2, look-up table 246 may be adapted to also store at least two values KT1 . . . KTm of a voltage controlled oscillator temperature co-efficient KT, and a frequency value F1 . . . Fm for each of the at least two values KT1 . . . KTm. Values F1 . . . Fm correspond to different output frequencies of voltage controlled oscillator 220. In this case, the value Vf is selected in dependence on both the temperature T measured by temperature sensor 244 and the frequency of the output signal 224 from voltage controlled oscillator 220.

Thus, elements of the example circuit of FIG. 2 may obviate the need for a bias voltage to be summed into the loop filter during normal operation, i.e. after lock has been achieved. As a consequence, the noise resulting from such a bias voltage in prior art systems does not arise with the phase-locked loop of the invention. In addition, no adjustment is made during operation of the phase locked loop, which eliminates the phase discontinuities that such adjustments involve. The hardware required may be significantly simpler than with prior art phase-locked loops of comparable performance, in particular those that rely on a temperature compensation loop that is active after the phase-locked loop has achieved lock.

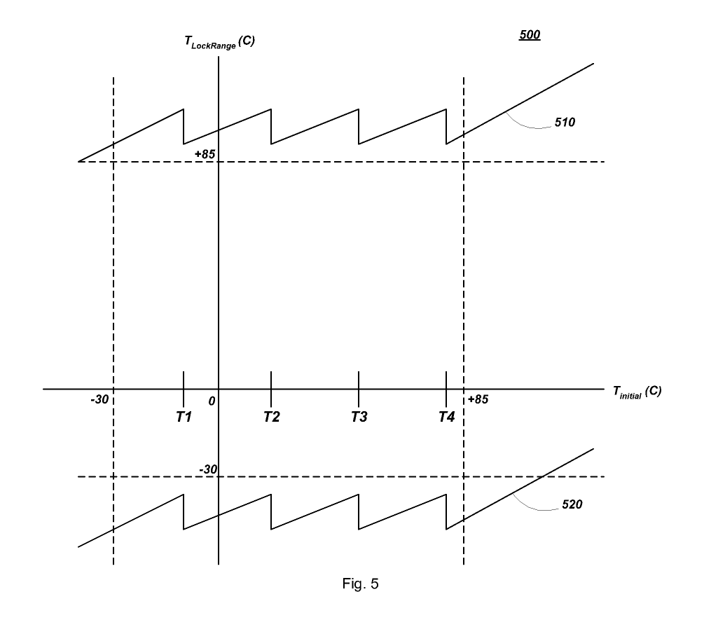

FIG. 5 illustrates a temperature tracking range that may be achievable in the example circuit of FIG. 2. The x-axis represents the ambient temperature T at which the phase locked loop is locked. The y-axis shows the limits of the temperature over which the phase locked loop is able to maintain lock in operation.

Curve 510 in FIG. 5 represents the limit of the maximum temperature over which lock may be maintained while keeping the tuning line voltage in the range between VLow_Limit and VHigh_Limit. Curve 520 represents the limit of the minimum temperature over which lock may be maintained while keeping the tuning line voltage in the range between VLow_Limit and VHigh_Limit. Temperatures T1 to T4 marked on FIG. 5 correspond to breakpoints stored in lookup table 246.

Table 1 below shows an example of the values that might be stored in lookup table 246. The right column of table 1 shows the Vf values Vf1 . . . Vfn. The left column shows ranges of ambient temperature value T measured when the digital tuning algorithm is initiated. The values Vf1 . . . Vfn in the right column correspond to each range of values of temperature T in the left column

TABLE 1

| Measured Initial | Forcing voltage Vf |
|---|---|
| Temperature (degrees C.) | (Volts) |
| <−5 | 0.6 |
| −5 to 15 | 0.65 |
| 15 to 35 | 0.7 |
| 35 to 55 | 0.75 |
| 55 to 100 | 0.8 |

The break points T1 to T4 on FIG. 5 are the maximum values of temperature for each of the lowest four ranges shown in the left column of Table 1. At each break point, the forcing voltage Vf applied to the loop during digital tuning takes on a different value. Each of the five successive Vf values used in the example of FIG. 5 and shown in Table 1 advantageously shifts the temperature tracking range of the phase locked loop to maximize operation over the target temperature range of use. This shifting of Vf during the digital tuning operation introduces the discontinuities or steps in the characteristics 510 and 520.

Curve 510 in FIG. 5 remains above +85C on the y-axis over a very wide range of initial temperature values. Similarly, curve 520 remains below −35C on the y-axis over a very wide range of initial temperature values. The result is a phase locked loop that:
(i) May meet exacting temperature specifications over a very wide range of temperatures in the ‘worst case scenario’, for example when tuning must begin at levels approaching the highest and lowest extremes of the operating range.
(ii) May have increased margins in typical operating scenarios. These margins may result in the phase locked loop being able to maintain lock when other circuit components are outside of their normal tolerances. Other circuit components might be outside their normal tolerances through ageing, for example, or if process variations have resulted in components that are outside of the planned manufacturing tolerances.

Both of (i) and (ii) may provide superior operating performance in a wireless communication unit, particularly one that may be operated under particularly hot or cold conditions.

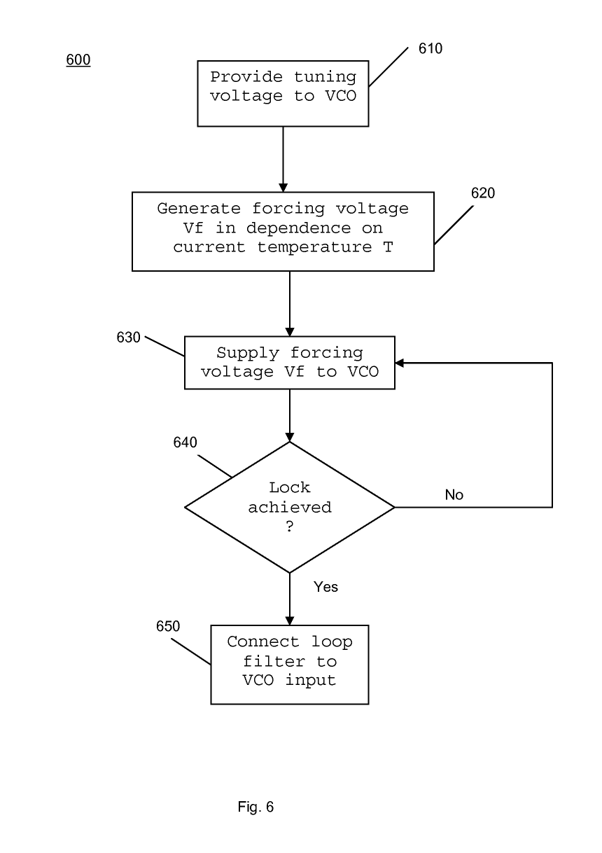

FIG. 6 represents an example of a method of tuning a phase-locked loop, in the form of a flowchart 600. Flowchart 600 shows a method of tuning a phase-locked loop for a wireless communications unit, the phase-locked loop comprising a voltage controlled oscillator that provides an output signal. Once the phase-locked loop has achieved lock, the output signal is of constant frequency.

In step 610, prior to the phase-locked loop achieving lock, the digital tuning subsystem 240 provides a tuning voltage to the voltage controlled oscillator. This was explained in connection with the example circuit of FIG. 2. The digital tuning subsystem 240 itself receives the output signal from the voltage controlled oscillator.

In step 620, a forcing voltage Vf is generated. The forcing voltage Vf depends on a current temperature value T. The forcing voltage Vf is selected from at least two predetermined forcing voltages Vf1 . . . Vfn.

In step 630, the forcing voltage Vf is supplied as the tuning line voltage to an input of the voltage controlled oscillator.

Decision step 640 involves making a decision about whether or not the phase-locked loop has achieved lock. If the phase-locked loop has not achieved lock, then the flowchart loops from decision 640 to step 630. The forcing voltage Vf is then applied to the tuning line of the voltage controlled oscillator for longer.

If the phase locked loop has achieved lock, then the flowchart proceeds from decision step 640 to step 650. In step 650, the forcing voltage Vf is no longer supplied. Instead, the output of a loop filter of the phase-locked loop is connected to the input of the voltage controlled oscillator.

Embodiments of the invention may also be implemented in a computer program for running on a computer system, at least including code portions for performing steps of a method according to the invention when run on a programmable apparatus, such as a computer system, or enabling a programmable apparatus to perform functions of a device or system according to the invention. The invention therefore also comprises a computer program, or a computer program product, adapted to implement the method of the invention.

The computer program may be provided on a data carrier, such as a CD-rom or diskette, stored with data loadable in a memory of a computer system, the data representing the computer program. The data carrier may further be a data connection, such as a telephone cable or a wireless connection.

In the foregoing specification, the invention has been described with reference to specific examples of embodiments of the invention. It will, however, be evident that various modifications and changes may be made therein without departing from the broader spirit and scope of the invention as set forth in the appended claims. For example, the connections may be a type of connection suitable to transfer signals from or to the respective nodes, units or devices, for example via intermediate devices. Accordingly, unless implied or stated otherwise the connections may for example be direct connections or indirect connections.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention.

Some of the above embodiments, as applicable, may be implemented using a variety of different information processing systems. Of course, the description of the architecture has been simplified for purposes of discussion, and it is just one of many different types of appropriate architectures that may be used in accordance with the invention.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediary components. Likewise, any two components so associated can also be viewed as being “operably connected,” or “operably coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Also, the aforementioned examples are not limited to physical devices or units implemented in non-programmable hardware but can also be applied in programmable devices or units able to perform the desired device functions by operating in accordance with suitable program code. Furthermore, the devices may be physically distributed over a number of apparatuses, while functionally operating as a single device. For example,

Also, devices functionally forming separate devices may be integrated in a single physical device.

Other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.”

The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. An integrated circuit comprising a digital phase-locked loop for a wireless communications unit, the digital phase-locked loop comprising:
a voltage controlled oscillator for providing an output signal;
a digital tuning subsystem, an input of the digital tuning subsystem being connected to the voltage controlled oscillator to receive the output signal, and an output of the digital tuning subsystem being connected to the voltage controlled oscillator;
a digital voltage generator for generating a forcing voltage, wherein the digital voltage generator is arranged:
to store at least two predetermined forcing voltages;
in dependence on a current temperature value and a voltage controlled oscillator temperature co-efficient corresponding to the frequency of the output signal, to select as the forcing voltage one of the at least two predetermined forcing voltages; and
to supply the selected forcing voltage as a tuning line voltage to the voltage controlled oscillator, prior to the phase locked loop achieving lock.

2. The integrated circuit of claim 1, further comprising:
a temperature sensor, the temperature sensor being adapted to provide the temperature of the voltage controlled oscillator at the start of the tuning phase, as the current temperature value.

3. The integrated circuit of claim 1, wherein the digital voltage generator comprises:
a look-up table, the look-up table being arranged to store each of the at least two predetermined forcing voltages together with an associated temperature value, wherein each of the at least two predetermined forcing voltages is a tuning line voltage to be applied when the current temperature value corresponds to the associated temperature value; and
a logic controller, the logic controller being arranged to select a forcing voltage from the at least two predetermined forcing voltages, based on the current temperature value.

4. The integrated circuit of claim 3, wherein the at least two predetermined forcing voltages correspond to voltages shown in the right column of the following table, and the associated temperature values correspond to temperatures shown in the left column:

| Measured Initial | Forcing voltage Vf |
|---|---|
| Temperature (degrees C.) | (Volts) |
| <−5 | 0.6 |
| −5 to 15 | 0.65 |
| 15 to 35 | 0.7 |
| 35 to 55 | 0.75 |
| 55 to 100 | 0.8 |

5. The integrated circuit of claim 3, wherein:
the look-up table is further arranged to store at least two values of a voltage controlled oscillator temperature co-efficient, and a frequency value for each of the at least two values of the voltage controlled oscillator temperature co-efficient;
the logic controller is further arranged to select the forcing voltage from the at least two predetermined forcing voltages, based on both the current temperature value and the voltage controlled oscillator temperature co-efficient corresponding to the frequency of the output signal.

6. The integrated circuit of claim 1, further comprising:
a divider, the divider being arranged to receive the output signal and to provide a divided signal;
a phase detector, the phase detector having a first input connected to a reference signal, and a second input connected to the output of the divider, the phase detector being adapted to provide a phase signal;
a loop filter, the input of the loop filter being connected to the output of the phase detector to receive the phase signal, and the output of the loop filter being selectably couplable to the input of the voltage controlled oscillator and wherein the digital voltage generator is selectably couplable to the input of the voltage controlled oscillator.

7. The integrated circuit of claim 6, further comprising a switch, the switch being arranged to connect to the input of the voltage controlled oscillator either:
the digital voltage generator; or
the output of the loop filter.

8. A wireless communication unit comprising the integrated circuit with a digital phase-locked loop of claim 1.

9. A method of tuning a phase-locked loop for a wireless communication unit, the phase-locked loop comprising a voltage controlled oscillator, the method comprising:
the voltage controlled oscillator providing an output signal;
during a tuning phase, prior to the phase-locked loop achieving lock:
providing a tuning voltage to the voltage controlled oscillator from a digital tuning subsystem the digital tuning subsystem receiving the output signal from the voltage controlled oscillator;
generating a forcing voltage in dependence on a current temperature value and a voltage controlled oscillator temperature co-efficient corresponding to the frequency of the output signal, the forcing voltage being selected from at least two predetermined forcing voltages;
supplying the forcing voltage as a tuning line voltage to the voltage controlled oscillator, prior to the phase-locked loop achieving lock.

10. The method of claim 9, further comprising:
measuring the temperature of the voltage controlled oscillator at the start of the tuning phase, to provide the current temperature value.

11. The method of claim 9, further comprising:
generating a forcing voltage for the current temperature value, that improves a tracking range of the phase-locked loop when the phase-locked loop is released to lock.

12. The method of claims 9, further comprising:
connecting the digital voltage generator to the input of the voltage controlled oscillator during the tuning phase, prior to the phase-locked loop achieving lock; and
connecting the output of a loop filter of the phase-locked loop to the input of the voltage controlled oscillator when the phase-locked loop has achieved lock.

13. A computer program product comprising program code for tuning a phase-locked loop for a wireless communications unit, the program code operable for:
providing an output signal by a voltage controlled oscillator;
during a tuning phase, prior to the phase-locked loop achieving lock:
providing a tuning voltage to the voltage controlled oscillator from a digital tuning subsystem, the digital tuning subsystem receiving the output signal from the voltage controlled oscillator;
generating a forcing voltage in dependence on a current temperature value and a voltage controlled oscillator temperature co-efficient corresponding to the frequency of the output signal, the forcing voltage being selected from at least two predetermined forcing voltages; and
supplying the forcing voltage to an input of the voltage controlled oscillator, prior to the phase-locked loop achieving lock.

14. The wireless communication unit of claim 8, further comprising:
a temperature sensor, the temperature sensor being adapted to provide the temperature of the voltage controlled oscillator at the start of the tuning phase, as the current temperature value.

15. The wireless communication unit of claim 8, wherein the digital voltage generator comprises:
a look-up table, the look-up table being arranged to store each of the at least two predetermined forcing voltages together with an associated temperature value, wherein each of the at least two predetermined forcing voltages is a tuning line voltage to be applied when the current temperature value corresponds to the associated temperature value; and
a logic controller, the logic controller being arranged to select a forcing voltage from the at least two predetermined forcing voltages, based on the current temperature value.

16. The wireless communication unit of claim 15, wherein the at least two predetermined forcing voltages correspond to voltages shown in the right column of the following table, and the associated temperature values correspond to temperatures shown in the left column:

| Measured Initial | Forcing voltage Vf |
|---|---|
| Temperature (degrees C.) | (Volts) |
| <−5 | 0.6 |
| −5 to 15 | 0.65 |
| 15 to 35 | 0.7 |
| 35 to 55 | 0.75 |
| 55 to 100 | 0.8 |

17. The wireless communication unit of claim 15, wherein:
the look-up table is further arranged to store at least two values of a voltage controlled oscillator temperature co-efficient, and a frequency value for each of the at least two values of the voltage controlled oscillator temperature co-efficient;
the logic controller is further arranged to select the forcing voltage from the at least two predetermined forcing voltages, based on both the current temperature value and the voltage controlled oscillator temperature co-efficient corresponding to the frequency of the output signal.

18. The wireless communication unit of claim 8, further comprising:
a divider, the divider being arranged to receive the output signal and to provide a divided signal;
a phase detector, the phase detector having a first input connected to a reference signal, and a second input connected to the output of the divider, the phase detector being adapted to provide a phase signal;
a loop filter, the input of the loop filter being connected to the output of the phase detector to receive the phase signal, and the output of the loop filter being selectably couplable to the input of the voltage controlled oscillator; and wherein the digital voltage generator is selectably couplable to the input of the voltage controlled oscillator.

19. The wireless communication unit of claim 6, further comprising a switch, the switch being arranged to connect to the input of the voltage controlled oscillator either:
the digital voltage generator; or
the output of the loop filter.
